(19) United States
(12) Patent Application Publication
(10) Pub. No.: US 2011/0127542 A1
(43) Pub. Date: Jun. 2, 2011

(54) SEMICONDUCTOR DEVICE AND METHOD OF FABRICATING THE SAME

(75) Inventor: Akira Hokazono, (US)

(73) Assignee: KABUSHIKI KAISHA TOSHIBA, Tokyo (JP)

(21) Appl. No.: 12/881,421

(22) Filed: Sep. 14, 2010

(30) Foreign Application Priority Data
Nov. 30, 2009 (JP) 2009-272191

(51) Int. Cl. H01L 29/78; H01L 21/336

(52) U.S. Cl. 257/77; 438/285; 257/E29.255; 257/E21.409

(57) ABSTRACT

According to one embodiment, a semiconductor device contains a gate electrode, SiGe layers, Si layers, source/drain regions, and silicide layers. The gate electrode is formed on a semiconductor substrate via a gate insulating film. The SiGe layers are formed on both sides of the gate electrode on the semiconductor substrate. Over half of a region of the SiGe layers is higher than an interface between the semiconductor substrate and the gate insulating film. The Si layers are formed on the SiGe layers. The source/drain regions are formed on both sides of the gate electrode in the Si layers, the SiGe layers and the semiconductor substrate. The silicide layers are formed on the Si layers.

### CROSS-REFERENCE TO RELATED APPLICATIONS

This application is based upon and claims the benefit of priority from prior Japanese Patent Application No. 2009-272191, filed on Nov. 30, 2009, the entire contents of which are incorporated herein by reference.

### FIELD

Embodiments described herein relate generally to a semiconductor device and a method of fabricating the same.

### BACKGROUND

A semiconductor device having a SiGe layer in a silicon substrate, a Si layer on the SiGe layer, and a silicide layer on the Si layer is known as a conventional semiconductor device. The semiconductor device is disclosed, for example, in JP-A-2008-159803.

According to the semiconductor device disclosed in JP-A-2008-159803, strain is generated in a channel region by the SiGe layer, thereby improving channel mobility. In addition, the silicide layer is formed on the Si layer, thereby increasing a distance between the silicide layer and a junction of a source/drain region, which can suppress increase of junction leakage.

### BRIEF DESCRIPTION OF THE DRAWING

FIG. 1 is a cross sectional view of a semiconductor device according to a first embodiment;

FIG. 2 is a cross sectional view of a semiconductor device according to the first embodiment;

FIGS. 3A to 3D are cross sectional views showing processes for fabricating the semiconductor device according to the first embodiment;

FIGS. 4A and 4B are charts respectively showing decreases of parasitic resistances in an n-type MOSFET and in a p type MOSFET.

FIG. 5 is a cross sectional view of a semiconductor device according to a second embodiment;

FIGS. 6A to 6D are cross sectional views showing processes for fabricating the semiconductor device according to the second embodiment;

FIG. 7 is a cross sectional view of a semiconductor device according to a third embodiment; and

FIGS. 8A to 8D are cross sectional views showing processes for fabricating the semiconductor device according to the third embodiment.

### DETAILED DESCRIPTION

According to one embodiment, a semiconductor device contains a gate electrode, SiGe layers, Si layers, source/drain regions, and silicide layers. The gate electrode is formed on a semiconductor substrate via a gate insulating film. The SiGe layers are formed on both sides of the gate electrode on the semiconductor substrate. Over half of a region of the SiGe layers is higher than an interface between the semiconductor substrate and the gate insulating film. The Si layers are formed on the SiGe layers. The source/drain regions are formed on both sides of the gate electrode in the Si layers, the SiGe layers and the semiconductor substrate. The silicide layers are formed on the Si layers.

### First Embodiment

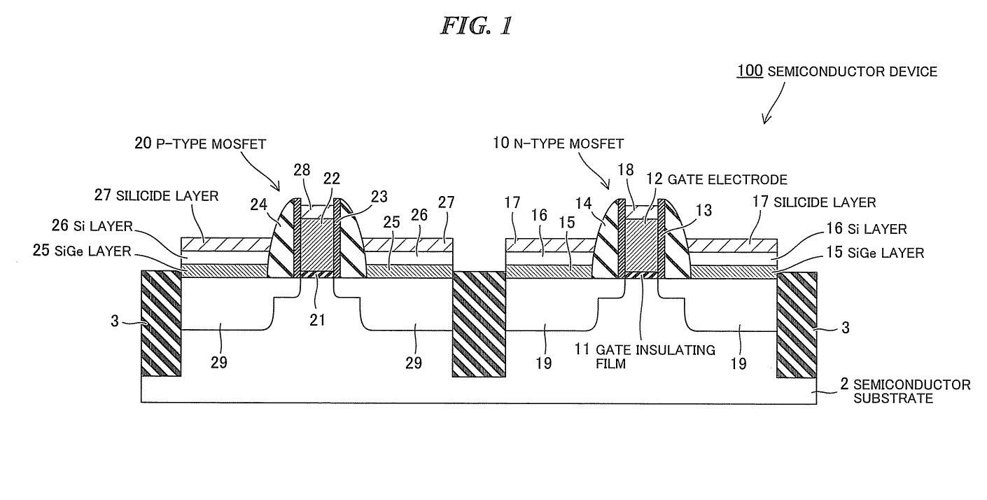

FIG. 1 is a cross sectional view of a semiconductor device 100 according to a first embodiment. The semiconductor device 100 has an n-type Metal Oxide Semiconductor Field Effect Transistor (MOSFET) 10, a p-type MOSFET 20, and an element isolation insulating film 3 formed on a semiconductor substrate 2 each. The element isolation insulating film 3 electrically isolates the n-type MOSFET 10 from the p-type MOSFET 20.

The semiconductor substrate 2 is made of Si-based crystal such as Si crystal.

The element isolation insulating film 3 is made of insulating material such as SiO₂ and has, for example, Shallow Trench Isolation (STI) structure 200-300 nm in depth.

The n-type MOSFET 10 contains a gate electrode 12 formed on the semiconductor substrate 2 via a gate insulating film 11, offset spacers 13 formed on both side surfaces of the gate electrode 12, gate sidewalls 14 formed on side surfaces of the offset spacers 13, SiGe layers 15 formed on both sides of the gate sidewalls 14 on the semiconductor substrate 2, Si layers 16 formed on the SiGe layers 15, silicide layers 17 formed on the Si layers 16, a silicide layer 18 formed on the gate electrode 12, and source/drain regions 19 formed on both sides of the gate electrode 12.

The p-type MOSFET 20 contains a gate electrode 22 formed on the semiconductor substrate 2 via a gate insulating film 21, offset spacers 23 formed on both side surfaces of the gate electrode 22, gate sidewalls 24 formed on side surfaces of the offset spacers 23, SiGe layers 25 formed on both sides of the gate sidewalls 24 on the semiconductor substrate 2, Si layers 26 formed on the SiGe layers 25, silicide layers 27 formed on the Si layers 26, a silicide layer 28 formed on the gate electrode 22, and source/drain regions 29 formed on both sides of the gate electrode 22.

The gate insulating films 11 and 21 are made of, for example, an insulating material such as SiO₂, SiN or SiON, or high-dielectric constant material such as HfSiON. The gate insulating films 11 and 21 have thickness of, for example, 0.5-6 nm.

The gate electrodes 12 and 22 are made of, for example, Si-based polycrystal such as Si polycrystal and contains a conductivity type impurity. In addition, the gate electrodes 12 and 22 may be a metal gate electrode made of metal, furthermore, may have a structure of two layers composed of a metal layer and a Si-based polycrystalline layer thereon. Note that, when the gate electrodes 12 and 22 are a metal gate electrode, the silicide layers 18 and 28 on the gate electrodes 12 and 22 are not formed. The gate electrodes 12 and 22 have thickness of, for example, 30-200 nm.

The offset spacers 13 and 23 and the gate sidewalls 14 and 24 are made of insulating material such as SiO₂ or SiN. In addition, the gate sidewalls 14 and 24 may have a structure of two layers made of different types of insulating material such as SiN, SiO₂ and Tetraethoxysilane (TEOS), or furthermore, a structure of three or more layers.

The SiGe layers 15 and 25 are made of SiGe crystal. The SiGe layers 15 and 25 are formed, for example, by epitaxial crystal growth using upper surfaces of the semiconductor substrate 2 as a base. A height of bottom surfaces of the SiGe layers 15 and 25 is substantially same as a height of an interface between the semiconductor substrate 2 and the gate insulating film 11 (a height of an interface between the semiconductor substrate 2 and the gate insulating film 21).

A SiGe crystal strains a Si crystal lattice-matched to the SiGe crystal because SiGe crystal has a larger lattice constant than Si crystal. Therefore, when a distance between a SiGe crystal and a channel region just below the gate insulating films 11 and 21 is small, the SiGe crystal generates compressive strain in the channel direction in the channel region. This may cause decrease of channel mobility (electronic mobility) in the n-type MOSFET.

However, the SiGe layers 15 and 25 do not exist at a position lower than the interface between the semiconductor substrate 2 and the gate insulating film 11, and are far from the channel region. Therefore, strain of a degree to affect the channel mobility is not generated in the channel region.

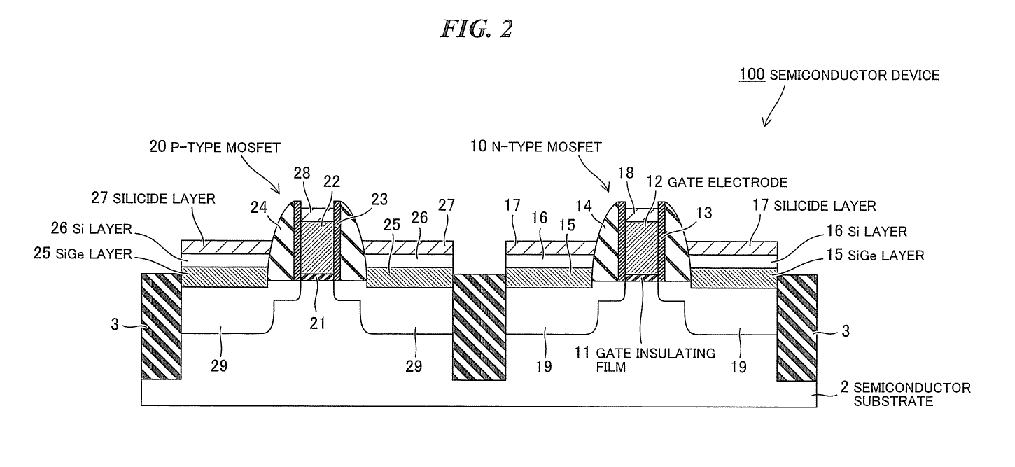

Note that, when a Ge density in the SiGe layer 15 is low (for example, not more than 10 atom %), difference of lattice constant between the SiGe crystal constituting the SiGe layer 15 and Si crystal is small, thus strain generated in the Si crystal is small, and as a result, strain of a degree to affect the channel mobility is not generated in the channel region. Therefore, in this case, the height of the bottom surfaces of the SiGe layers 15 and 25 may be lower than the height of the interface between the semiconductor substrate 2 and the gate insulating film 11 as shown in FIG. 2.

In addition, when strain of a degree to affect the channel mobility is not generated in the channel region because over half of the region of the SiGe layers 15 and 25 is higher than the interface between the semiconductor substrate 2 and the gate insulating film 11, the height of the bottom surfaces of the SiGe layers 15 and 25 may be lower than the height of the interface between the semiconductor substrate 2 and the gate insulating film 11.

The Si layers 16 and 26 are made of Si crystal. The Si layers 16 and 26 are formed, for example, by epitaxial crystal growth using upper surfaces of the SiGe layers 15 and 25 as a base.

The source/drain regions 19 are formed in the Si layers 16, the SiGe layers 15 and the semiconductor substrate 2. In addition, the source/drain regions 29 are formed in the Si layers 26, the SiGe layers 25 and the semiconductor substrate 2.

The conductivity type impurity of the source/drain regions 19 is concentrated in the Si layers 16 sandwiched between the silicide layers 17 and the SiGe layers 15, thereby decreasing contact resistance at interfaces between the silicide layers 17 and the Si layers 16. In addition, the conductivity type impurity of the source/drain regions 29 is concentrated in the Si layers 26 sandwiched between the silicide layers 27 and the SiGe layers 25, thereby decreasing contact resistance at interfaces between the silicide layers 27 and the Si layers 26.

The SiGe layers 15 and 25 have a function to suppress diffusion of the conductivity type impurity and concentrate the conductivity type impurity into the Si layers 16 and 26. The Ge density in the SiGe layers 15 and 25 is preferably 20 atom or more in order to more effectively suppress diffusion of the conductivity type impurities and concentrate the conductivity type impurities into the Si layers 16 and 26. Note that, the Ge density in the SiGe layers 15 and 25 is preferably 30 atom %- or less in order to suppress generation of crystal defect in the SiGe layers 15 and 25.

The silicide layers 17, 27, 18 and 28 are made of metal silicide containing metal such as Ni, Co, Er, Pt or Pd.

An example of a method of fabricating the semiconductor device 100 according to the present embodiment will be described hereinafter.

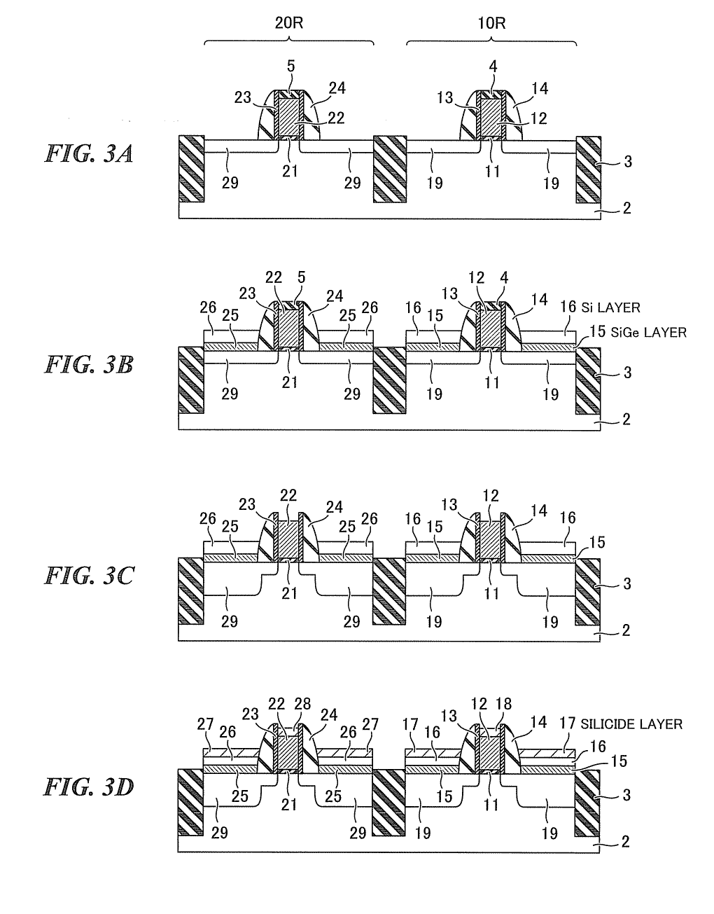

FIGS. 3A to 3D are cross sectional views showing processes for fabricating the semiconductor device 100 according to the first embodiment.

Firstly, as shown in FIG. 3A, after an n-type MOSFET region 10R and a p-type MOSFET region 20R are laid out by forming the element isolation insulating film 3 into the semiconductor substrate 2, the gate insulating film 11, the gate electrode 12, a cap layer 4, the offset spacer 13, shallow regions of the source/drain region 19, and the gate sidewall 14 are formed in the n-type MOSFET region 10R, and the gate insulating film 21, the gate electrode 22, a cap layer 5, the offset spacer 23, shallow regions of the source/drain region 29, and the gate sidewall 24 are formed in the p-type MOSFET region 20R.

In addition, although it is not shown in the figures, a p-type well and an n-type channel region are formed into the n-type MOSFET region 10R after the element isolation insulating film 3 is formed. For example, when the p-type well is formed using B, ion implantation is carried out under a condition in which an implantation energy is 260 keV and a dosage is 2.0×10¹³ cm⁻². Meanwhile, when the n-type channel region is formed using As, ion implantation is carried out under a condition in which an implantation energy is 80 keV and a dosage is 1.0×10¹³ cm⁻².

Furthermore, although it is not shown in the figures, a n-type well and a p-type channel region are formed into the p-type MOSFET region 20R. For example, when the n-type well is formed using P, ion implantation is carried out under a condition in which an implantation energy is 500 keV and a dosage is 3.0×10¹³ cm⁻². Meanwhile, when the p-type channel region is formed using B, ion implantation is carried out under a condition in which an implantation energy is 10 keV and a dosage is 1.5×10¹³ cm⁻².

Note that, these ion implantations are carried out through a 10 nm or less thick natural oxide film on the semiconductor substrate 2. After that, heat treatment such as Rapid Thermal Annealing (RTA) is carried out in order to activate the conductivity type impurity in the wells and the channel regions.

The gate insulating films 11 and 21, the gate electrodes 12 and 22, the cap layers 4 and 5, the offset spacers 13 and 23, the shallow regions of the source/drain region 19 and 29, and the gate sidewalls 14 and 24 are formed, for example, by following method.

Firstly, after the wells and the channel regions are formed, the natural oxide film on the semiconductor substrate 2 is removed, and then material films of the gate insulating films 11 and 21 such as SiO₂ films, material films of the gate electrodes 12 and 22 such as polycrystalline Si films, and material films of the cap layers 4 and 5 such as SiN films are formed. The material films of the gate insulating films 11 and 21 are formed on the semiconductor substrate 2 by thermal oxidation method, Low-Pressure Chemical Vapor Deposition (LPCVD) method, or the like. The material films of the gate electrodes 12 and 22 and the material films of the cap layers 4 and 5 are formed on the material films of the gate insulating films 11 and 21 by LPCVD method.

Next, the laminated material films are patterned by lithography method (optical lithography method, X-ray lithography method or electron beam lithography method) and Reactive Ion Etching (RIE) method, and then shaped into the cap layers 4 and 5, the gate electrodes 12 and 22, and the gate insulating films 11 and 21.

Next, after a SiO₂ film is formed 1-2 nm in thickness on the surfaces of the gate electrodes 12 and 22 by thermal oxidation method, a SiO₂ film or the like is formed 3-12 nm in thickness thereon by LPCVD method. Then these films are shaped into the offset spacers 13 and 23 by RIE method.

Next, conductivity type impurities are implanted into the n-type MOSFET region 10R and the p-type MOSFET region 20R by ion implantation procedure using the offset spacers 13 and 23 and the cap films 4 and 5 as a mask, thereby forming p-type halo regions (not shown), n-type halo regions (not shown) and the shallow regions of the source/drain regions 19 and 29. Furthermore, heat treatment such as spike annealing is carried out in order to activate the implanted conductivity type impurities.

Here, when the p-type halo regions are formed by using BF₂, for example, the ion implantation is carried out under a condition in which implantation energy is 20 KeV, implantation dose is 3.0×10¹³ cm⁻², and implantation angle (an angle with reference to a direction vertical to the surface of the semiconductor substrate 2) is 30°. In addition, when the shallow regions of the n-type source/drain regions 19 are formed by using As, for example, the ion implantation is carried out under a condition in which implantation energy is 1-5 KeV, implantation dose is from 5.0×10¹⁴ to 1.5×10¹⁵ cm⁻².

Moreover, when the n-type halo regions are formed by using As, for example, the ion implantation is carried out under a condition in which implantation energy is 40 KeV, implantation dose is 3.0×10¹³ cm⁻², and implantation angle (an angle with reference to a direction vertical to the surface of the semiconductor substrate 2) is 30°. In addition, when the shallow regions of the p-type source/drain regions 29 are formed by using BF₂, for example, the ion implantation is carried out under a condition in which implantation energy is 1-3 KeV, implantation dose is from 5.0×10¹⁴ to 1.5×10¹⁵ cm⁻².

Next, a SiO₂ film or the like is formed on the entire surface of the semiconductor substrate 2 by LPCVD method, and is shaped into the gate sidewalls 14 and 24 by RIE method.

Next, as shown in FIG. 3B, the SiGe layers 15 and 25 and the Si layers 16 and 26 are formed on the both sides of the gate sidewalls 14 and 24 on the semiconductor substrate 2.

Concretely, for example, the semiconductor substrate 2 is heated in hydrogen atmosphere under high temperature of 700° C. or more, and material gas of Si, such as SiH₄, SiH₂Cl₂ or SiHCl₃, and material gas of Ge, such as GeH₄, are supplied on the semiconductor substrate 2 with HCl gas, hydrogen gas, etc., thereby epitaxially growing SiGe crystals on the semiconductor substrate 2, which forms the SiGe layers 15 and 25.

Then material gas of Si, such as SiH₄, SiH₂Cl₂ or SiHCl₃, is supplied on the semiconductor substrate 2 with HCl gas, hydrogen gas, etc., thereby epitaxially growing Si crystals on the SiGe layers 15 and 25, which forms the Si layers 16 and 26.

Next, as shown in FIG. 3C, deep high-concentration regions of the source/drain region 19 and 29 are formed after the cap films 4 and 5 are removed.

Concretely, for example, after the cap films 4 and 5 are removed by RIE method or wet etching method using phosphoric acid heated to 170° C., conductivity type impurities are implanted into the n-type MOSFET region 10R and the p-type MOSFET region 20R by ion implantation procedure using the offset spacers 13 and 23 and the gate sidewalls 14 and 24 as a mask, thereby forming the deep high-concentration regions of the source/drain regions 19 and 29. Furthermore, heat treatment such as spike annealing is carried out in order to activate the implanted conductivity type impurities.

The deep high-concentration regions of the source/drain regions 19 are formed by implanting n-type conductivity type impurities, such as As or P, into the Si layers 16, the SiGe layers 15 and the semiconductor substrate 2 in the n-type MOSFET region 10R. In addition, the deep high-concentration regions of the source/drain regions 29 are formed by implanting p-type conductivity type impurities, such as B or BF₂, into the Si layers 26, the SiGe layers 25 and the semiconductor substrate 2 in the p-type MOSFET region 20R.

Next, as shown in FIG. 3D, the silicide layers 17 and 27 are formed on the Si layers 16 and 26, and the silicide layers 18 and 28 are formed on the gate electrodes 12 and 22.

An example of a method of forming the silicide layers 17, 27, 18 and 28 made of Ni silicide will be described hereinafter. Firstly, natural oxide films on the Si layers 16 and 26 and on the gate electrodes 12 and 22 are removed by hydrofluoric acid treatment. Next, after a Ni film is formed on the whole surface of the semiconductor substrate 2 by sputtering method or the like, silicidation reaction is generated between the Ni film and the Si layers 16 and 26 and between the Ni film and the gate electrodes 12 and 22 by heat treatment such as RTA under the temperature condition of 400-500° C., thereby forming the silicide layers 17, 27, 18 and 28. Next, unreacted portions of the Ni film are removed using mixed solution of sulfuric acid and hydrogen peroxide solution, or the like.

Note that, a process in which a TiN film is formed on the Ni film after the Ni film is formed may be carried out. In addition, a two step annealing process may be carried out. In the two step annealing process, the Ni film is formed, is heated using low temperature RTA at 250-400° C., is etched using the mixed solution of sulfuric acid and hydrogen peroxide solution, and is heated again using RTA at 400-550° C. for reducing sheet resistance.

In this step, only an upper portion of the Si layers 16 and 26 are silicided. Accordingly, the Si layers 16 remain between the SiGe layers 15 and the silicide layers 17, and the Si layers 26 remain between the SiGe layers 25 and the silicide layers 27. The conductivity type impurities in the silicided portions of the Si layers 16 and 26 are extruded to the non-silicided portions by the forming of the silicide layers 17 and 27, and the SiGe layers 15 and 25 suppress diffusion of the extruded conductivity type impurities. As a result, the conductivity type impurities are concentrated into the Si layers 16 between the SiGe layers 15 and the silicide layers 17 and into the Si layers 26 between the SiGe layers 25 and the silicide layers 27, thereby decreasing contact resistances at the interfaces between the silicide layers 17 and the Si layers 16 and at the interfaces between the silicide layers 27 and the Si layers 26.

In addition, since the height of the bottom surfaces of the SiGe layers 15 is not lower than the height of the interface between the semiconductor substrate 2 and the gate insulating film 11, decrease of channel mobility in the n-type MOSFET 10 can be suppressed.

Furthermore, parasitic resistances of both the n-type MOSFET region 10R and the p-type MOSFET region 20R are decreased in few process because the SiGe layers 15 and the SiGe layers 25 can be formed in the same process at the same time, the Si layers 16 and the Si layers 26 can be formed in the same process at the same time, and the silicide layers 17 and the silicide layers 27 can be formed in the same process at the same time.

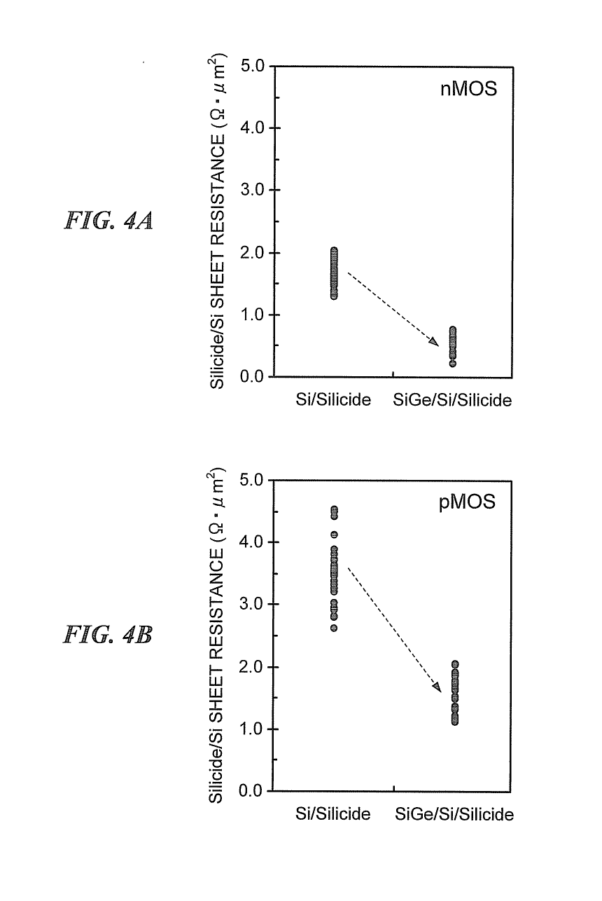

FIGS. 4A and 4B are charts respectively showing decreases of parasitic resistances in the n-type MOSFET region 10R and in the p-type MOSFET region 20R. The group of the dots in the left side in each of FIGS. 4A and 4B shows sheet resistances (electric resistances per unit area) at an interface between a silicide layer and a Si layer when the silicide layer is directly formed on the Si layer, as well as a structure of conventional MOSFETs. In addition, the group of the dots in the right side in FIG. 4A shows sheet resistances at the interface between the silicide layers 17 and the Si layers 16, and the group of the dots in the right side in FIG. 4B shows sheet resistances at the interface between the silicide layers 27 and the Si layers 26.

FIGS. 4A and 4B show that contact resistance at an interface between a silicide layer and a Si layer is lower in both the n-type MOSFET region 10R and the p-type MOSFET region 20R than in a structure of conventional MOSFETs.

### Second Embodiment

A second embodiment is different from the first embodiment in that the SiGe layers 15 and 25 are formed on elevated Si layers. Note that, the explanations for the same points as the first embodiment will be omitted or simplified.

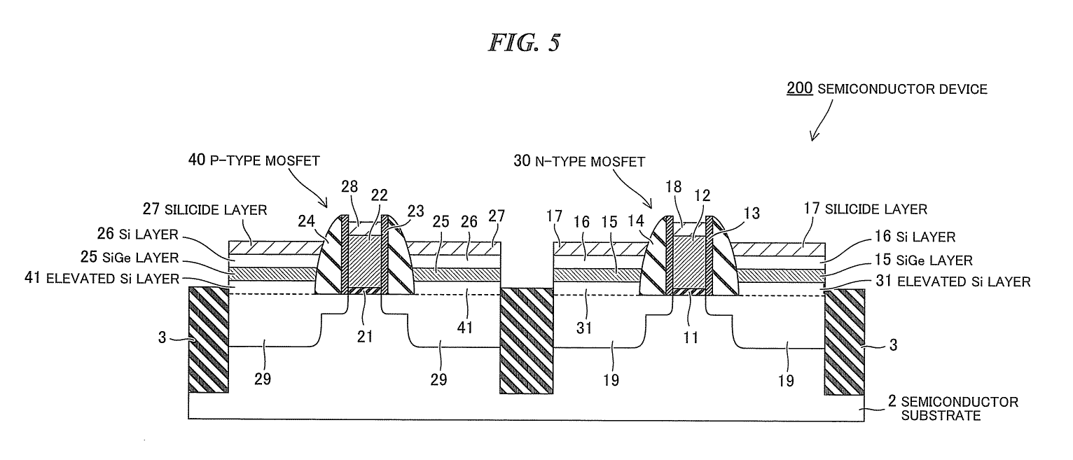

FIG. 5 is a cross sectional view of a semiconductor device 200 according to a second embodiment. The semiconductor device 200 has an n-type MOSFET 30, a p-type MOSFET 40, and the element isolation insulating film 3 formed on a semiconductor substrate 2 each. The element isolation insulating film 3 electrically isolates the n-type MOSFET 30 from the p-type MOSFET 40.

The n-type MOSFET 30 contains the gate electrode 12 formed on the semiconductor substrate 2 via the gate insulating film 11, the offset spacers 13 formed on the both side surfaces of the gate electrode 12, the gate sidewalls 14 formed on the side surfaces of the offset spacers 13, elevated Si layers 31 formed on the both sides of the gate sidewalls 14 on the semiconductor substrate 2, the SiGe layers 15 formed on the elevated Si layers 31, the Si layers 16 formed on the SiGe layers 15, the silicide layers 17 formed on the Si layers 16, the silicide layer 18 formed on the gate electrode 12, and the source/drain regions 19 formed on the both sides of the gate electrode 12.

The p-type MOSFET 40 contains the gate electrode 22 formed on the semiconductor substrate 2 via the gate insulating film 21, the offset spacers 23 formed on the both side surfaces of the gate electrode 22, the gate sidewalls 24 formed on the side surfaces of the offset spacers 23, elevated Si layers 41 formed on the both sides of the gate sidewalls 24 on the semiconductor substrate 2, the SiGe layers 25 formed on the elevated Si layers 41, Si layers 26 formed on the SiGe layers 25, the silicide layers 27 formed on the Si layers 26, the silicide layer 28 formed on the gate electrode 22, and the source/drain regions 29 formed on the both sides of the gate electrode 22.

The elevated Si layers 31 and 41 are made of Si crystal. The elevated Si layers 31 and 41 are formed, for example, by epitaxial crystal growth using the upper surfaces of the semiconductor substrate 2 as a base. A height of upper surfaces of the elevated Si layers 31 and 41 is higher than the height of the interface between the semiconductor substrate 2 and the gate insulating film 11.

The SiGe layers 15 and 25 are formed, for example, by epitaxial crystal growth using upper surfaces of the elevated Si layers 31 and 41 as a base. A height of bottom surfaces of the SiGe layers 15 and 25 is higher than the height of the interface between the semiconductor substrate 2 and the gate insulating film 11 because the SiGe layers 15 and 25 is formed on the elevated Si layers 31 and 41.

The source/drain regions 19 are formed in the Si layers 16, the SiGe layers 15, the elevated Si layers 31 and the semiconductor substrate 2. In addition, the source/drain regions 29 are formed in the Si layers 26, the SiGe layers 25, the elevated Si layers 41 and the semiconductor substrate 2.

The conductivity type impurity of the source/drain regions 19 is concentrated in the Si layers 16 sandwiched between the silicide layers 17 and the SiGe layers 15, thereby decreasing contact resistance at the interfaces between the silicide layers 17 and the Si layers 16. In addition, the conductivity type impurity of the source/drain regions 29 is concentrated in the Si layers 26 sandwiched between the silicide layers 27 and the SiGe layers 25, thereby decreasing contact resistance at the interfaces between the silicide layers 27 and the Si layers 26.

An example of a method of fabricating the semiconductor device 200 according to the present embodiment will be described hereinafter.

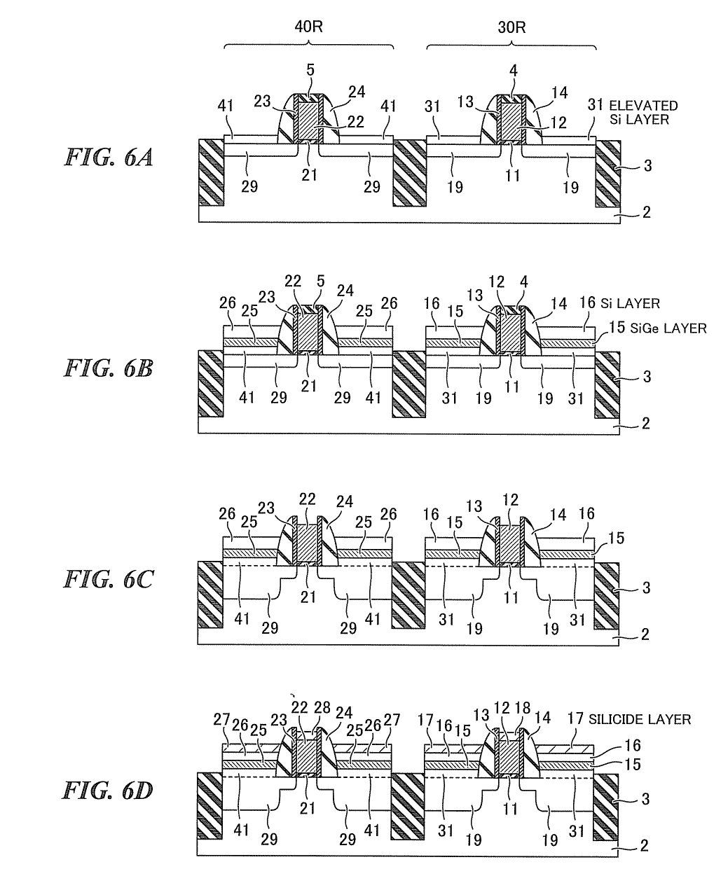

FIGS. 6A to 6D are cross sectional views showing processes for fabricating the semiconductor device 200 according to the second embodiment.

Firstly, the processes until forming the gate sidewalls 14 and 24, shown in FIG. 3A, are carried out in the same way as the first embodiment.

Next, as shown in FIG. 6A, the elevated Si layers 31 and 41 are formed on the both sides of the gate sidewalls 14 and 24 on the semiconductor substrate 2. The elevated Si layers 31 and 41 are formed by the same method as the Si layers 16 and 26. Note that, elevated Si:C layers made of Si:C crystal may be formed instead of the elevated Si layers 31 and 41.

Next, as shown in FIG. 6B, the SiGe layers 15 and 25 and the Si layers 16 and 26 are formed on the elevated Si layers 31 and 41.

Next, as shown in FIG. 6C, the deep high-concentration regions of the source/drain region 19 and 29 are formed after the cap films 4 and 5 are removed.

The deep high-concentration regions of the source/drain regions 19 are formed by implanting n-type conductivity type impurities, such as As or P, into the Si layers 16, the SiGe layers 15, the elevated Si layers 31 and the semiconductor substrate 2 in the n-type MOSFET region 30R. In addition, the deep high-concentration regions of the source/drain regions 29 are formed by implanting p-type conductivity type impurities, such as B or BF₂, into the Si layers 26, the SiGe layers 25, the elevated Si layers 41 and the semiconductor substrate 2 in the p-type MOSFET region 40R.

Next, as shown in FIG. 6D, the silicide layers 17 and 27 are formed on the Si layers 16 and 26, and the silicide layers 18 and 28 are formed on the gate electrodes 12 and 22.

In this step, only upper portions of the Si layers 16 and 26 are silicided. Accordingly, the Si layers 16 remain between the SiGe layers 15 and the silicide layers 17, and the Si layers 26 remain between the SiGe layers 25 and the silicide layers 27. The conductivity type impurities in the silicided portions of the Si layers 16 and 26 are extruded to the non-silicided portions by the forming of the silicide layers 17 and 27, and the SiGe layers 15 and 25 suppress diffusion of the extruded conductivity type impurities. As a result, the conductivity type impurities are concentrated into the Si layers 16 between the SiGe layers 15 and the silicide layers 17 and into the Si layers 26 between the SiGe layers 25 and the silicide layers 27, thereby decreasing contact resistances at the interfaces between the silicide layers 17 and the Si layers 16 and at the interfaces between the silicide layers 27 and the Si layers 26.

According to the second embodiment, distances between the SiGe layers 15 and the channel region and between the SiGe layers 25 and the channel region can be larger because the SiGe layers 15 and 25 are formed on the elevated Si layers 31 and 41. As a result, decrease of channel mobility in the n-type MOSFET 30 can be suppressed effectively.

### Third Embodiment

A third embodiment is different from the first embodiment in that strained-Si technique is applied to fabrication of n-type and p-type MOSFETs. Note that, the explanations for the same points as the first embodiment will be omitted or simplified.

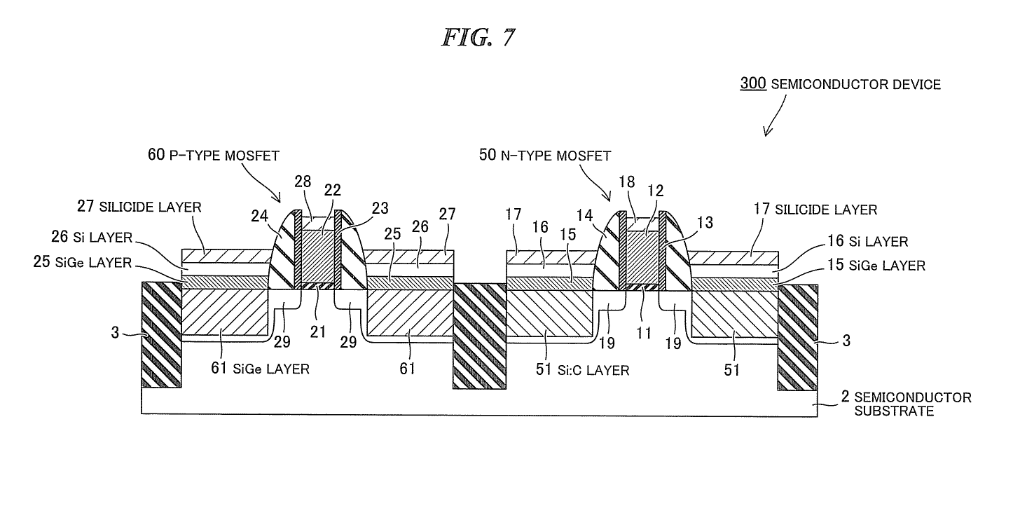

FIG. 7 is a cross sectional view of a semiconductor device 300 according to a third embodiment. The semiconductor device 300 has an n-type MOSFET 50, a p-type MOSFET 50, and the element isolation insulating film 3 formed on a semiconductor substrate 2 each. The element isolation insulating film 3 electrically isolates the n-type MOSFET 50 from the p-type MOSFET 60.

The n-type MOSFET 50 contains the gate electrode 12 formed on the semiconductor substrate 2 via the gate insulating film 11, the offset spacers 13 formed on the both side surfaces of the gate electrode 12, the gate sidewalls 14 formed on the side surfaces of the offset spacers 13, Si:C layers 51 formed on the both sides of the gate sidewalls 14 in the semiconductor substrate 2, the SiGe layers 15 formed on the Si:C layers 51, the Si layers 16 formed on the SiGe layers 15, the silicide layers 17 formed on the Si layers 16, the silicide layer 18 formed on the gate electrode 12, and the source/drain regions 19 formed on the both sides of the gate electrode 12.

The p-type MOSFET 60 contains the gate electrode 22 formed on the semiconductor substrate 2 via the gate insulating film 21, the offset spacers 23 formed on the both side surfaces of the gate electrode 22, the gate sidewalls 24 formed on the side surfaces of the offset spacers 23, SiGe layers 61 formed on the both sides of the gate sidewalls 24 in the semiconductor substrate 2, the SiGe layers 25 formed on the SiGe layers 61, the Si layers 26 formed on the SiGe layers 25, the silicide layers 27 formed on the Si layers 26, the silicide layer 28 formed on the gate electrode 22, and the source/drain regions 29 formed on the both sides of the gate electrode 22.

A Si:C crystal strains a Si crystal lattice-matched to the Si:C crystal because Si:C crystal has a smaller lattice constant than Si crystal. Accordingly, the Si:C layers 51 can generate tensile strain in the channel direction in the channel region of the n-type MOSFET 50, thereby increasing channel mobility (mobility of electron). Note that, a layer that consists of crystal having smaller lattice constant than Si crystal other than Si:C crystal may be used instead of the Si:C layers 51.

A C density of the Si:C layers 51 is preferably 0.5-3.0 atom %. C densities lower than 0.5 atom % is too low to adequately increase channel mobility in the n-type MOSFET 50. In addition, there is a high possibility that C densities higher than 3 atom % cause crystal defects in the Si:C layers 51.

A SiGe crystal strains a Si crystal lattice-matched to the SiGe crystal because SiGe crystal has a larger lattice constant than Si crystal. Accordingly, the SiGe layers 61 can generate compressive strain in the channel direction in the channel region of the p-type MOSFET 60, thereby increasing channel mobility (mobility of hole). Note that, a layer that consists of crystal having larger lattice constant than Si crystal other than SiGe crystal may be used instead of the SiGe layers 61.

A Ge density of the SiGe layers 61 is preferably 5-30 atom %. Ge densities lower than 5 atom % is too low to adequately increase channel mobility in the p-type MOSFET 60. In addition, there is a high possibility that Ge densities higher than 30 atom % cause crystal defects in the SiGe layers 61.

The source/drain regions 19 are formed in the Si layers 16, the SiGe layers 15, the Si:C layers 51 and the semiconductor substrate 2. In addition, the source/drain regions 29 are formed in the Si layers 26, the SiGe layers 25, the SiGe layers 61 and the semiconductor substrate 2.

The conductivity type impurity of the source/drain regions 19 is concentrated in the Si layers 16 sandwiched between the silicide layers 17 and the SiGe layers 15, thereby decreasing contact resistance at the interfaces between the silicide layers 17 and the Si layers 16. In addition, the conductivity type impurity of the source/drain regions 29 is concentrated in the Si layers 26 sandwiched between the silicide layers 27 and the SiGe layers 25, thereby decreasing contact resistance at the interfaces between the silicide layers 27 and the Si layers 26.

An example of a method of fabricating the semiconductor device 300 according to the present embodiment will be described hereinafter.

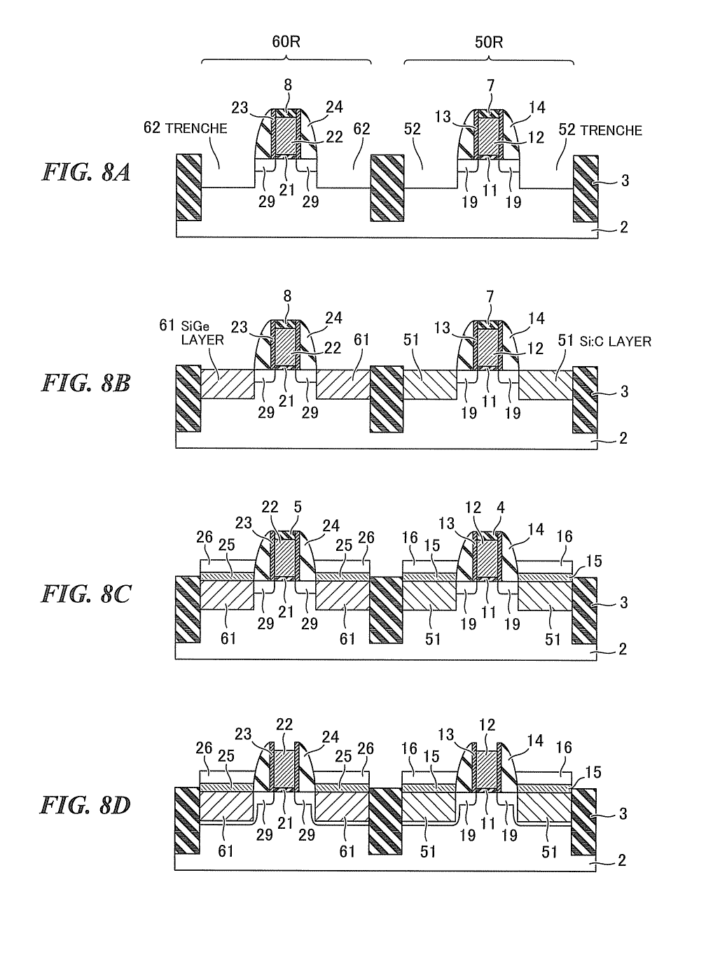

FIGS. 8A to 8D are cross sectional views showing processes for fabricating the semiconductor device 300 according to the third embodiment.

Firstly, the processes until forming the gate sidewalls 14 and 24, shown in FIG. 3A, are carried out in the same way as the first embodiment.

Next, as shown in FIG. 8A, the semiconductor substrate 2 is etched by using the cap layers 4 and 5, the offset spacers 13 and 23, and the gate sidewalls 14 and 24 as an etching mask, thereby respectively forming trenches 52 and 62 in the n-type MOSFET region 50R and the p-type MOSFET region 60R.

Next, as shown in FIG. 8B, Si:C crystals and SiGe crystals are epitaxially grown so as to be buried into trenches 52 and 62, respectively, by using surfaces of the semiconductor substrate 2 exposed in inner surfaces of trenches 52 and 62, thereby forming the Si:C layers 51 and the SiGe layers 61.

Concretely, for example, the semiconductor substrate 2 is heated in hydrogen atmosphere under high temperature of 700° C. or more, and material gas of Si, such as SiH₄, SiH₂Cl₂ or SiHCl₃, and material gas of C, such as SiH₃CH₃, are supplied on the semiconductor substrate 2 with HCl gas, hydrogen gas, etc., thereby epitaxially growing Si:C crystals in the trenches 52, which forms the Si:C layers 51.

For example, material gas of Si, such as SiH₄, SiH₂Cl₂ or SiHCl₃, and material gas of Ge, such as GeH₄, is supplied on the semiconductor substrate 2 with HCl gas, hydrogen gas, etc., thereby epitaxially growing SiGe crystals in the trenches 62, which forms the SiGe layers 61.

Next, as shown in FIG. 8C, the SiGe layers 15 and the Si layers 16 are formed on the Si:C layers 51, and the SiGe layers 25 and the Si layers 26 are formed on the SiGe layers 61.

Next, as shown in FIG. 8D, the deep high-concentration regions of the source/drain region 19 and 29 are formed after the cap films 4 and 5 are removed.

The deep high-concentration regions of the source/drain regions 19 are formed by implanting n-type conductivity type impurities, such as As or P, into the Si layers 16, the SiGe layers 15, the Si:C layers 51 and the semiconductor substrate 2 in the n-type MOSFET region 50R. In addition, the deep high-concentration regions of the source/drain regions 29 are formed by implanting p-type conductivity type impurities, such as B or BF₂, into the Si layers 26, the SiGe layers 25, the SiGe layers 61 and the semiconductor substrate 2 in the p-type MOSFET region 60R.

Subsequently, the silicide layers 17 and 27 is formed on the Si layers 16 and 26 in the same way as the first embodiment, thereby forming the silicide layers 18 and 28 on the gate electrodes 12 and 22.

In this step, only upper portions of the Si layers 16 and 26 are silicided. Accordingly, the Si layers 16 remain between the SiGe layers 15 and the silicide layers 17, and the Si layers 26 remain between the SiGe layers 25 and the silicide layers 27. The conductivity type impurities in the silicided portions of the Si layers 16 and 26 are extruded to the non-silicided portions by the forming of the silicide layers 17 and 27, and the SiGe layers 15 and 25 suppress diffusion of the extruded conductivity type impurities. As a result, the conductivity type impurities are concentrated into the Si layers 16 between the SiGe layers 15 and the silicide layers 17 and into the Si layers 26 between the SiGe layers 25 and the silicide layers 27, thereby decreasing contact resistances at the interfaces between the silicide layers 17 and the Si layers 16 and at the interfaces between the silicide layers 27 and the Si layers 26.

According to the third embodiment, the formation of the Si:C layers 51 and the SiGe layers 61 is effective in increasing channel mobility in the n-type MOSFET 50 and the p-type MOSFET 60.

Note that, since the height of the bottom surfaces of the SiGe layers 15 is not lower than the height of the interface between the semiconductor substrate 2 and the gate insulating film 11, like the first embodiment, decrease of channel mobility in the n-type MOSFET 50 can be suppressed.

According to the first to third embodiments, the conductivity type impurities are concentrated in the Si layers 16 sandwiched between the silicide layers 17 and the SiGe layers 15 and in the Si layers 26 sandwiched between the silicide layers and the SiGe layers 25, thereby decreasing contact resistances at the interfaces between the silicide layers 17 and the Si layers 16 and at the interfaces between the silicide layers 27 and the Si layers 26. As a result, parasitic resistances of the n-type MOSFET and the p-type MOSFET can be decreased.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

For example, Si:C layers made of Si:C crystal may be used instead of the SiGe layers 15 and 25 in the first to third embodiments. The Si:C layers have a function to suppress diffusion of conductivity type impurities extruded by the forming of the suicide layers 17 and 27, like the SiGe layers 15 and 25.

Note that, a C density of the Si:C layers is preferably 0.3 atom % or more in order to more effectively suppress diffusion of the conductivity type impurities and more effectively concentrate the conductivity type impurities. In addition, the C density in the Si:C layers is preferably 3.0 atom % or less in order to suppress generation of crystal defect in the Si:C layers.

In this case, since a height of bottom surfaces of the Si:C layers is not lower than the height of the interface between the semiconductor substrate 2 and the gate insulating film 11, decrease of channel mobility in the p-type MOSFET can be suppressed. Note that, when strain of a degree to affect the channel mobility is not generated in the channel region because over half of the region of the Si:C layers is higher than the interface between the semiconductor substrate 2 and the gate insulating film 11, the height of the bottom surfaces of the Si:C layers may be lower than the height of the interface between the semiconductor substrate 2 and the gate insulating film 11.

The Si:C layers may be formed by the same method as the SiGe layers 15 and 25.

What is claimed is:

1. A semiconductor device, comprising:
a gate electrode formed on a semiconductor substrate via a gate insulating film;
SiGe layers formed on both sides of the gate electrode on the semiconductor substrate, over half of a region of the SiGe layers being higher than an interface between the semiconductor substrate and the gate insulating film;
Si layers formed on the SiGe layers;
source/drain regions formed on both sides of the gate electrode in the Si layers, the SiGe layers and the semiconductor substrate; and
silicide layers formed on the Si layers.

2. The semiconductor device according to claim 1, wherein a height of bottom surfaces of the SiGe layers is not lower than a height of the interface between the semiconductor substrate and the gate insulating film.

3. The semiconductor device according to claim 2, wherein a Ge density in the SiGe layers is not lower than 20 atom % and is not higher than 30 atom %.

4. The semiconductor device according to claim 2, wherein the SiGe layers are formed on the semiconductor substrate via elevated layers, the elevated layers being made of Si crystal or Si:C crystal.

5. The semiconductor device according to claim 1, wherein the source/drain regions are n-type.

6. The semiconductor device according to claim 5, wherein the semiconductor substrate is made of Si crystal; and
Si:C layers are formed in regions of the semiconductor substrate, the regions being under the SiGe layers.

7. A semiconductor device, comprising:
a gate electrode formed on a semiconductor substrate via a gate insulating film;
Si:C layers formed on both sides of the gate electrode on the semiconductor substrate, over half of a region of the Si:C layers being higher than an interface between the semiconductor substrate and the gate insulating film;
Si layers formed on the Si:C layers;
source/drain regions formed on both sides of the gate electrode in the Si layers, the Si:C layers and the semiconductor substrate; and
silicide layers formed on the Si layers.

8. The semiconductor device according to claim 7, wherein a height of bottom surfaces of the Si:C layers is not lower than a height of the interface between the semiconductor substrate and the gate insulating film.

9. The semiconductor device according to claim 8, wherein a C density in the Si:C layers is not lower than 0.3 atom % and is not higher than 3.0 atom %.

10. The semiconductor device according to claim 8, wherein the Si:C layers are formed on the semiconductor substrate via elevated layers, the elevated layers being made of Si crystal or Si:C crystal.

11. The semiconductor device according to claim 7, wherein the source/drain regions are p-type.

12. The semiconductor device according to claim 11, wherein the semiconductor substrate is made of Si crystal; and
SiGe layers are formed in regions of the semiconductor substrate, the regions being under the Si:C layers.

13. A method of fabricating a semiconductor device, comprising:
forming a gate electrode on a semiconductor substrate via a gate insulating film;
forming semiconductor layers on both sides of the gate electrode on the semiconductor substrate, the semiconductor layers being made of SiGe crystal or Si:C crystal, a height of bottom surfaces of the semiconductor layers being not lower than a height of an interface between the semiconductor substrate and the gate insulating film;
forming Si layers on the semiconductor layers;
implanting an n-type impurity into the Si layers, the semiconductor layers and the semiconductor substrate to form at least a portion of source/drain regions; and
siliciding an upper portion of the Si layers to form silicide layers.

14. The method of fabricating a semiconductor device according to claim 13, further comprising:
forming elevated semiconductor layers on the semiconductor substrate, the elevated semiconductor layers being made of Si crystal of Si:C crystal,
wherein the semiconductor layers are formed on the elevated semiconductor layers.

15. The method of fabricating a semiconductor device according to claim 13, wherein the semiconductor layers are made of SiGe crystal of which a Ge density is not lower than 20 atom % and is not higher than 30 atom %.

16. The method of fabricating a semiconductor device according to claim 13, wherein the semiconductor layers are made of Si:C crystal of which a C density is not lower than 0.3 atom % and is not higher than 3.0 atom %.

17. The method of fabricating a semiconductor device according to claim 13, wherein the semiconductor layers are made of SiGe crystal; and
the source/drain regions are n-type.

18. The method of fabricating a semiconductor device according to claim 17, further comprising:
forming trenches on both sides of the gate electrode in the semiconductor substrate; and
epitaxially forming Si:C crystals in the trenches to form Si:C layers,
wherein the semiconductor substrate is made of Si crystal; and
the semiconductor layers are formed on the Si:C layers.

19. The method of fabricating a semiconductor device according to claim 13, wherein the semiconductor layers are made of Si:C crystal; and
the source/drain regions are p-type.

20. The method of fabricating a semiconductor device according to claim 19, further comprising:
forming trenches on both sides of the gate electrode in the semiconductor substrate; and
epitaxially forming SiGe crystals in the trenches to form SiGe layers,
wherein the semiconductor substrate is made of Si crystal; and
the semiconductor layers are formed on the SiGe layers.
